(19) United States
(12) Patent Application Publication
(10) Pub. No.: US 2018/0166596 A1
(43) Pub. Date: Jun. 14, 2018

(54) Photo-Controllable Composite Dielectric Material

(71) Applicants: Kevin A. Boulais, La Plata, MD (US); Michael S. Lowry, Fredericksburg, VA (US); Simin Feng, Oxnard, CA (US); Robert B. Nichols, Yorktown, VA (US); Mark E. Preddy, Fredericksburg, VA (US)

(72) Inventors: Kevin A. Boulais, La Plata, MD (US); Michael S. Lowry, Fredericksburg, VA (US); Simin Feng, Oxnard, CA (US); Robert B. Nichols, Yorktown, VA (US); Mark E. Preddy, Fredericksburg, VA (US)

(73) Assignee: United States of America, as represented by the Secretary of the Navy, Arlington, VA (US)

(21) Appl. No.: 15/602,205

(22) Filed: May 23, 2017

Related U.S. Application Data
(60) Provisional application No. 62/341,024, filed on May 24, 2016.

(51) Int. Cl. H01L 31/0352; B82Y 20/00; H01L 31/18; H01L 31/09

(52) U.S. Cl. CPC H01L 31/035218; H01L 31/095; H01L 31/18; B82Y 20/00

(57) ABSTRACT

A photoconductive device is provided for changing dielectric properties in response to select electromagnetic radiation. The device includes an optical core, an optical filter disposed on the core, and an optically clear insulator disposed on the filter. One example core is a quantum dot. Another example core is an optically clear core overlaid by a photoconductive coating disposed thereon.

### CROSS REFERENCE TO RELATED APPLICATION

Pursuant to 35 U.S.C. § 119, the benefit of priority from provisional application 62/341,024, with a filing date of May 24, 2016, is claimed for this non-provisional application.

### STATEMENT OF GOVERNMENT INTEREST

The invention described was made in the performance of official duties by one or more employees of the Department of the Navy, and thus, the invention herein may be manufactured, used or licensed by or for the Government of the United States of America for governmental purposes without the payment of any royalties thereon or therefor.

### BACKGROUND

The invention relates generally to dielectric material having controllability by photons. In particular, the invention relates to a composite material having photo-controllable dielectric properties.

Composite dielectrics have attracted interest because their electromagnetic properties can be controlled synthetically. In particular, the process of mixing several dielectric components together to achieve a final effective permittivity is useful for many electromagnetic applications and examples have been available for more than a century.

As one example, there may be a need for a particular permittivity to obtain a specific electromagnetic impedance to minimize radio frequency (RF) reflection. A composite material in which at least one of the components is a good conductor has been referred to as an artificial dielectric (W. E. Kock, “Metallic delay lenses,” Bell Systems Technical Journal 27 (1) 59-82, January 1948).

The term “artificial dielectric” is used to distinguish the polarization properties of a conductor from that of an insulating dielectric. The conductor includes what artisans of ordinary skill recognize as “free” charge, whereas a dielectric insulator consists of “bound” charge. Either will achieve a similar polarization response to an applied electric field.

### SUMMARY

Conventional dielectric materials yield disadvantages addressed by various exemplary embodiments of the present invention. In particular, exemplary embodiments provide a photoconductive device for changing dielectric properties in response to select electromagnetic radiation. The device includes an optical core, an optical filter disposed on the core, and an optically clear insulator disposed on the filter. One example core is a quantum dot. Another example core is an optically clear core overlaid by a photo-conductive layer.

### BRIEF DESCRIPTION OF THE DRAWINGS

These and various other features and aspects of various exemplary embodiments will be readily understood with reference to the following detailed description taken in conjunction with the accompanying drawings, in which like or similar numbers are used throughout, and in which:

FIG. 1 is a graphical view of permittivity variation with frequency for different particulate conductivity values;

FIG. 2 is a cross-section view of a photoconductive device; and

FIG. 3 is an electrical schematic view of the photoconductive device;

FIG. 4 is a cross-section view of a quantum dot device; and

FIG. 5 is an electrical schematic view of the quantum dot device.

### DETAILED DESCRIPTION

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

The selection of materials with a desired conductivity can be limiting in nature. In the case of a crystalline or organic semiconductors, conductivity is often controlled by doping the material with impurities. The absorption rate can be high when bandgap material is used since direct electron-hole pair generation stems from the lattice atoms instead of the impurities. High absorption can be a good thing since it enhances sensitivity to light, but can also be a not desirable due to limits imposed on the penetration depth of light. In the case of composite dielectrics, high absorption could limit the light from reaching particulates that are deeper within the material and the controllability of the composite dielectric would be diminished.

For the aforementioned case that used USI particulates, light absorption was minimal enabling photons to reach particulates very deep within the composite. This was due to use of a light wavelength that only interacted with deep level traps within the material, such as K. A. Boulais et al.: “Circuit analysis of photosensitive capacitance in semi-insulating GaAs,” IEEE Trans. Electron Devices, ED-60 793-798 (2013). Direct electron-hole pair generation was suppressed. The tradeoff was that this lowered the sensitivity to light, and restricted the operable frequency range unless high intensity light was used.

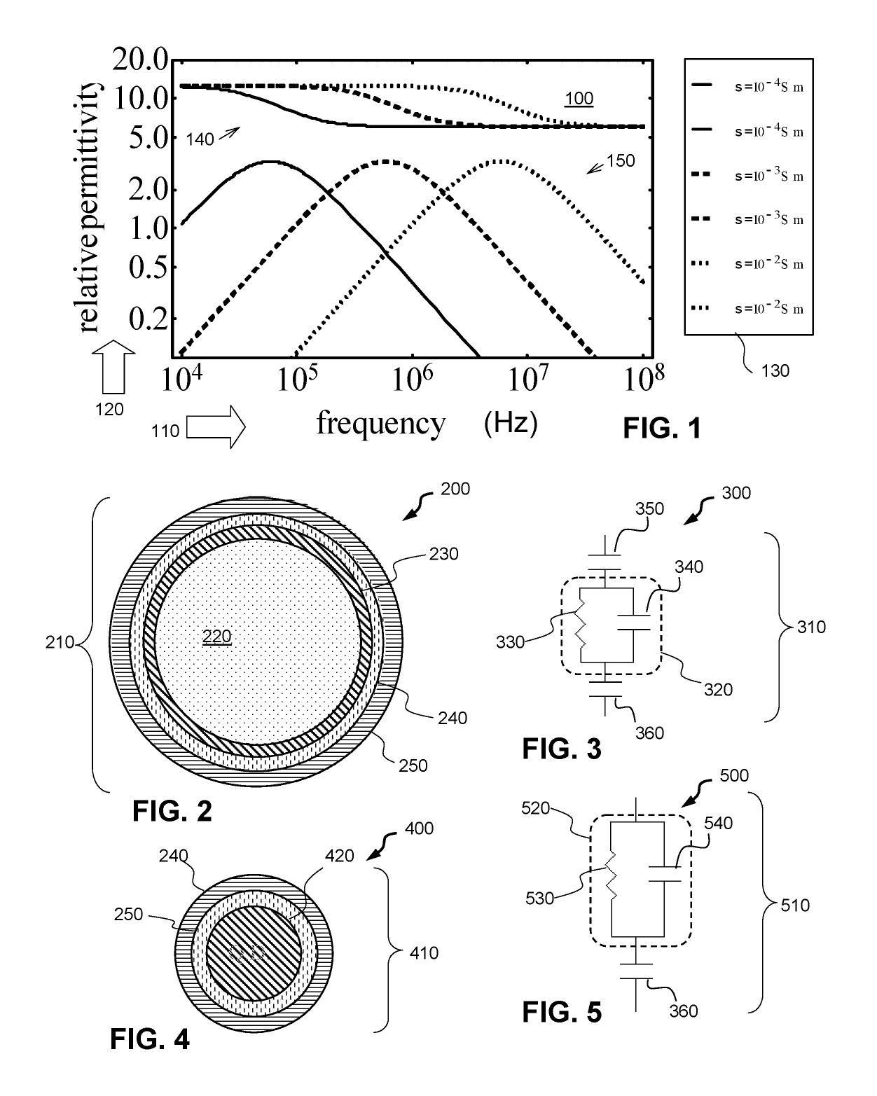

FIG. 1 shows a graphical view 100 of permittivity variation with frequency. The abscissa 110 denotes frequency in cycles-per-second (Hz), while the ordinate 120 denotes relative permittivity. A legend 130 identifies the real (upper) 140 and imaginary (lower) 150 curves for permittivity of three different photo-conductivities. These correspond to the particulates as solid lines at 10⁴, dash lines at 10³ and dot lines at 10².

Such a photo-controllable composite dielectric has been demonstrated in which the photo-conductive particulate was undoped semi-insulating (USI) gallium arsenide (GaAs) and the binder component was poly(methyl methacrylate/urethane) (PMMA/U) resin.

Three curves showing the variation in permittivity for three different conductivity values. By increasing the conductivity, for example by photo-injection, the curves sweep from left to right. At a given frequency, the material can exhibit a corresponding increase in the effective permittivity. The top curves are the real part, and the bottom curves are the imaginary part of the permittivity.

As can be observed by the dotted curve for the longest wavelengths, a higher conductivity range is necessary to control the permittivity at around 10⁷ Hz. Using higher intensity light enables this to be accomplished, but this technique lacks efficiency because much of the energy would be employed merely to shift the curve to the higher range of frequencies. A more advantageous solution is to incorporate a material with a higher dark value of conductivity. Then a lower intensity of light would be necessary to sweep the curve past 10⁷ Hz. This makes a more controllable composite dielectric that is more sensitive to light.

A dynamic photo-variable dielectric response can be realized by using a photo-conductive material as a component in the composite dielectric from H. Kallman et al., “Induced conductivity in luminescent powders. II. AC impedance measurements,” Phys. Rev., 89 (4) 700-707 (1953)). The dielectric permittivity constant of a photo-conductive material can be represented by the complex relation:

$${ɛ}_{p} = {ɛ}_{p}^{′} - j \frac{σ}{ω} \qquad ( 1 )$$

where ε′ₚ is the real part of the permittivity, j=\sqrt{−1} is the imaginary number, σ is the photo-conductivity, w is the angular frequency and the subscript p means photo-conductive particulate. In eqn. (1), the imaginary component depends only on conductivity and is assumed to be much larger than from other dielectric loss effects. For an insulating binder, the permittivity can be represented simply as ε_{b}, where the subscript b refers to the binder. Many dielectric mixing equations exist depending on geometrical and material parameters. One popular mixing equation known by those artisans of ordinary skill is the equation from K. Lichtenecker: “Die Dielektrizitäts-konstante natürlicher and kunstlicher Mischkörper,” Physik. Zeits. 27 (1926)) expressed here as:

ε=εₚ^{f}^{ₚ}ε_{b}^{1-f}^{ₚ} (2)

where fₚ is the volumetric fill factor of the particulate. Although eqn. (2) is written for a two-component composite dielectric, this can be extended to multiple components and is generally appropriate for mixtures that are symmetric, meaning that geometrically the particles can be interchanged and the equation remains valid.

For the case that the photo-conductive component is within an insulating binder material, then another relation has been shown to be effective from Kevin A. Boulais et al.: “Optically Controllable Composite Dielectric Based on Photo-conductive Particulates”, IEEE Trans. Microwave Theory and Techniques, 62 (7), 1448-1453 (June, 2014).

$${ɛ}_{e} = \frac{{ɛ}_{b} ( {ɛ}_{b} + ( {ɛ}_{p} - {ɛ}_{b} ) {f}^{2 / 3} )}{{ɛ}_{b} + ( {ɛ}_{p} - {ɛ}_{b} ) ( {f}^{2 / 3} - f )} \qquad ( 3 )$$

In eqn. (3) the materials are not symmetric as might be the case for conducting particulates and an insulating and otherwise continuous binder.

Incorporating eqn. (1) into eqn. (3), the effective permittivity is found to change with conductivity. FIG. 1 illustrates a plot of eqn. (3) for three different conductivity values, with the top curves 140 representing the real part of the permittivity, while the bottom curves 150 are the imaginary part of the permittivity, which shows frequency dispersion. As conductivity increases, the curves sweep from left to right towards higher frequencies. As the curves sweep past a selected frequency, the effective permittivity changes, thus showing photo-control of the permittivity.

FIG. 2 shows a cross-section view 200 of an exemplary composite dielectric 210 forming a spherical shape. An optically clear core 220 forms a substrate in the geometric center, surrounded by a photo-conductive coating 230. This is further enveloped by an optical filter 240 and an optically clear insulator 250. Artisans of ordinary skill will recognize that the shape can form alternatives to a sphere while remaining within the scope of the invention, such as cubes and other related forms.

FIG. 3 shows an electrical diagram view 300 of electrical components that comprise a composite 310 analogous to the dielectric 210. A photo-band gap parallel circuit 320 representing the photoconductive coating 230 includes a photo-band gap resistor 330 and a photo-band gap capacitor 340. Insulator layer capacitors 350 and 360 flank each terminal of the circuit 320.

FIG. 4 shows a cross-section view 400 of an exemplary quantum dot assembly 410 forming a spherical shape. A light-emitting quantum dot 420 is surrounded by the optical filter 240, which is enveloped by the optically clear insulator 250.

FIG. 5 shows an electrical diagram view 500 of electrical components that comprise a quantum dot assembly 510. A quantum dot parallel circuit 520 includes a quantum dot resistor 530 and a quantum dot capacitor 540. An insulator layer capacitor 360 is disposed at one terminal of the circuit 520

Exemplary embodiments provide techniques for employing materials in photo-controllable composite dielectrics using high photo-absorptive materials. Practical photo-controllable composite dielectrics require tradeoffs in design to achieve a desired parameter space of operation. One tradeoff is the desire to use highly photo-conductive particulates as the active component in the composite, which has the detrimental effect of limiting the thickness of the material to very thin geometries.

This balance between “photo-sensitivity” and material thickness is overcome by the incorporation of a layered shell of active material. The shell or clear insulator 250 enables the same electric polarization as a solid material, but light only passes through a thin shell thereby minimizing attenuation. In turn, light can then reach active particulates located deeper within the composite dielectric enhancing the “photo-sensitivity” effect.

Exemplary embodiments relate to a photo-controllable composite dielectric in which the active particulates can be highly photo-absorptive, thus minimizing the need for a tradeoff between optical sensitivity and composite material thickness. In these embodiments, optical absorption is controlled geometrically instead of by material properties alone. Thus, highly absorptive materials can be used while permitting light to penetrate deeper into the composite dielectric to reach particulate throughout. This process removes the restriction of low optical absorption for a tunable composite dielectric such as in the case of USI as presented above. In turn, this technique enables new materials to be used that can cover a broader range of frequencies while at the same time having higher sensitivity to light.

View 200 shows an exemplary geometry in the shape of a sphere. The embodiments shown do not restrict the inventive concept to a spherical shape, but in fact such shapes can include cubes, ellipsoids or any other shape. (note that Cubes and ellipsoids have a higher random close packing factor than spheres. See: A. Donev et al.: “Improving the Density of Jammed Disordered Packings using Ellipsoids”, Science, 303, 990-993 (2004).

Enhanced packing may permit higher loading concentrations for exemplary embodiments in an ink and may improve performance. An optically transparent core 220 forms the basis over which to deposit layers. The core 220 is transparent to the controlling wavelength of interest. The outer layer 250 is an electrical insulating and optically transparent layer. Its insulating nature is necessary so that particulates don't conduct electrical current between each other in the case that they touch. This is known as electrical percolation and could reduce the controllable permittivity effect. One exemplary geometry shows a high optical absorptive material being employed while nonetheless permitting light to pass through efficiently.

The optical filter 240 is a filtering layer that can be used to select or limit the wavelength of light that the composite dielectric 210 is sensitive to. This could be advantageous when the material is designed to respond to one specific color of light only, and be immune to fluorescent room lighting, for example. This concept should not be limited to placing the optical filter 240 as the inner shell 230. In fact, a dual purpose outer shell 250 could be used that is electrically insulating and optically filtering. Finally, the inner shell 230 is the active photoconductor material. Here any range of photo-conductivity can be used without concern of high optical absorption.

An example of a material might be a semi-conductor that photo-conducts by light absorption creating direct electron-hole pairs. Absorption in many such materials can be excessive, thereby limiting light penetration (in microns) to 100 μm for example. Thus, for the shell 230 being only 1 μm thick, light can reach approximately fifty particulates deep.

To be effective, light must penetrate the shell 250 twice—once on entrance and once on exit, and also that one can neglect the effects where light strikes the side walls for simplicity in explanation. Moreover, multiple layers of filter 240 and photo-conductive 230 materials stacked could be fabricated to make very selective multi-mode photo-controllable composite dielectrics 210. View 300 shows an electrical circuit diagram for the schematic model 310 of stacking photo-band gap material. By the second layer the light energy is in the preferred wavelength and penetrates deeper as the filter requirements diminish.

Operation is achieved by introducing or removing light to the core 220. This changes the band gap of the photo conductive material 230 and changes resistance of the photo-band gap and capacitance of various photo band gap materials. By adding an insulator material 250 to the outside of the structure this enables only a change in capacitance of exemplary embodiments. Without the insulator 250, resistances can shift with capacitance reactance. Changing width, height, and the shape of the connecting areas to exemplary embodiments yields different static and active measured capacitances.

For select embodiments, custom quantum dots 420 can be engineered larger so the band gap size enables specific wave length to pass through. In turn this acts as a filter to reduce shorter wave length light from going through and could prevent core damage. The outer shell 250 acts as an insulator to avoid electrical connection of the quantum dots. The optical filter inner shell 240 combined with the clear outer shell 250 behaves as an aggregate optical filter. This is advantageous if the material is designed to respond to one specific color of light only. The inner core 420 can be any type of photo-conductive material.

This type of photoconductive composite particle is relatively easier to fabricate compared to the one in view 200 with conventional nanofabrication technologies. FIG. 4 shows the elevation cross-section view 400 featuring a schematic of a composite particle 410 based on a quantum dot (QD) 420. The photoconductive quantum dot 420 can be composed of example core materials such as quartz, sapphire, glass, and polymers. Example polymers include poly(methyl methacrylate) (PMMA, a thermoplastic polymer), polystyrene, etc., used in spectroscopic studies. The quantum dot 420 is coated by two optically transparent thin-layer materials: the optical filter 240 and the optically clear insulator 250. FIG. 5 shows the diagram view 500 of a circuit model 510 of the QD composite photoconductive particle 410.

Examples of photo-conductive coatings such as the filter 240 and the insulator 250 include various metal oxides and polymers: modified zinc oxides, zirconium-tin oxide, titanium oxides, thiophene octamer and enhanced photoactive organic polymers, such as polyaniline, polyvinyl carbazole, and modified versions thereof, as well as photoactive polynuclear coordination compounds, such as one-dimensional chains consisting of bridging ligands with iron, cobalt or other metal ions, are some examples. The solvents listed are volatile materials, technically considered “binders” in the literature.

For example, acetone (a volatile solvent) has been used to soften the binder (PMMA). The acetone evaporated and, upon its evaporation, the binder re-solidified. Specifying the binder as a thermoplastic polymer or a thermosetting polymer is presumed to be preferable. The inclusion of elastomers as a specific example is appropriate because these can be either thermoplastic or thermosetting. A list of volatile solvents may be appropriate if the intent is for this to be a dispersion that can be added to other matrices (e.g., a thermoplastic polymer ink mixture), but in that instance the solvents serve as a carrier rather than a binder.

Examples of optical filter 240 include: band pass, broadband pass, long wave pass, short wave pass, and edge pass are some examples. Materials such as lithium fluoride and magnesium fluoride could be employed. Examples of outer insulator 250 include: modified hot dip polymers, fluid bed powder epoxy, dip or spin coated barium titanate, enhanced urethanes, and ultrasonic spray deposition of modified polymer, are some examples.

Example of binder material: special polysiloxane mix such as low viscosity polydimethylsiloxane (PDMS), modified acrylic lacquers and other polymers. In addition modified elastomers like thermoplastic rubbers, vinyl, thermosetting acrylic and silicon could also be employed. Examples of photo-conductive coating 230 include n-polyvinylcarbazole (C₁₄H₁₁N), lead sulfide (PbS) and selenium (Se). Examples of nanoparticle material for the QD 420 include silicon (Si), cadmium selenide (CdSe), cadmium sulfide (CdS) and indium arsenide (InAs).

While certain features of the embodiments of the invention have been illustrated as described herein, many modifications, substitutions, changes and equivalents will now occur to those skilled in the art. It is, therefore, to be understood that the appended claims are intended to cover all such modifications and changes as fall within the true spirit of the embodiments.

1. A photoconductive device for changing dielectric capacitance in response to select electromagnetic radiation, said device comprising:
an optically clear core;
a photoconductive coating disposed on said core, said coating producing a parallel electric circuit having a capacitor and a resistor;
an optical filter disposed on said coating; and
an optically clear insulator disposed on said filter.

2. The device according to claim 1, wherein said device forms a sphere.

3. A photoconductive device for changing dielectric capacitance in response to select electromagnetic radiation, said device comprising:
a quantum dot core, said core producing a parallel electric circuit having a capacitor and a resistor;
an optical filter disposed on said core; and
an optically clear insulator disposed on said filter.

4. The device according to claim 3, wherein said device forms a sphere.

5. The device according to claim 1, wherein said coating is composed from one of n-polyvinylcarbazole (C₁₄H₁₁N), lead sulfide (PbS) and selenium (Se).

6. The device according to claim 3, wherein said quantum dot is composed from one of silicon (Si), cadmium sulfide (CdS) and indium arsenide (InAs).
